(19) United States
(12) Patent Application Publication
(10) Pub. No.: US 2026/0182304 A1
(43) Pub. Date: Jun. 25, 2026

(54) ELECTROSTATIC CHUCK

(71) Applicant: TOTO LTD., Fukuoka (JP)

(72) Inventors: Yuma OKUBO, Fukuoka (JP); Tomoki UMETSU, Fukuoka (JP)

(73) Assignee: TOTO LTD., Fukuoka (JP)

(21) Appl. No.: 19/424,929

(22) Filed: Dec. 18, 2025

(30) Foreign Application Priority Data
Dec. 25, 2024 (JP) 2024-228719

(51) Int. Cl. H10P 72/72; H01J 37/32

(52) U.S. Cl. CPC H10P 72/722; H01J 37/32715; H01J 2237/2007

(57) ABSTRACT

An electrostatic chuck 10 includes a dielectric substrate 100 including a surface 110 as a mounting surface, a heater 140 provided inside the dielectric substrate 100, and an attraction electrode 130 provided inside the dielectric substrate 100 at a position closer to the surface 110 side than the heater 140. Both the heater 140 and the attraction electrode 130 are configured such that a plurality of ceramic particles CP are disposed inside a conductor. The heater 140 is thicker than the attraction electrode 130. In the electrostatic chuck 10, an average particle diameter of the ceramic particles CP disposed inside the heater 140 is 50% or more and 150% or less of an average particle diameter of the ceramic particles CP disposed inside the attraction electrode 130.

### CROSS-REFERENCE TO RELATED APPLICATION

This application is based upon and claims the benefit of priority from Japanese Patent Application No. 2024-228719 filed on Dec. 25, 2024, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate provided with an attraction electrode. When a voltage is applied to the attraction electrode, an electrostatic force is generated, and the wafer mounted on the dielectric substrate is attracted and held.

The above-described attraction electrode is often provided as a conductive layer embedded inside the dielectric substrate. As such a conductive layer, for example, a heater or an RF electrode may be provided in addition to the above-described attraction electrode. A thickness of each conductive layer is individually set in accordance with its function. Accordingly, a plurality of conductive layers inside the dielectric substrate are generally different from each other in thickness.

As described in Japanese Patent No. 7111522, a plurality of ceramic particles may be disposed inside the conductive layers. With such a configuration, adhesion between the ceramics constituting the dielectric substrate and the conductive layers inside the dielectric substrate can be ensured.

### SUMMARY

In manufacturing the electrostatic chuck, the dielectric substrate is formed by laminating a plurality of green sheets. The conductive layers are formed by printing a paste-like material on surfaces of some of the green sheets before lamination.

The thickness of each conductive layer is generally adjusted in accordance with particle diameters of ceramic particles mixed into the paste. For example, when using a paste mixed with ceramic particles having a relatively small average particle diameter, the conductive layer formed by printing the paste becomes thin. On the other hand, when using a paste mixed with ceramic particles having a relatively large average particle diameter, the conductive layer formed by printing the paste becomes thick.

However, when the particle diameters of the ceramic particles contained in the conductive layer are excessively large, adhesion between the ceramics constituting the dielectric substrate and the conductive layer is reduced.

The present invention has been made in view of such a problem and aims at providing an electrostatic chuck capable of ensuring adhesion between a dielectric substrate and a conductive layer.

To solve the above-described problem, the electrostatic chuck according to the present invention includes: a dielectric substrate having a mounting (placement) surface on which a workpiece (an object) to be electrostatically attracted is mounted (placed); a first conductive layer provided inside the dielectric substrate; and a second conductive layer provided inside the dielectric substrate at a position closer to the mounting surface side than the first conductive layer. Both the first conductive layer and the second conductive layer are configured such that a plurality of ceramic particles are disposed inside a conductor. The first conductive layer is thicker than the second conductive layer. In this electrostatic chuck, an average particle diameter of ceramic particles disposed inside the first conductive layer is 50% or more and 150% or less of an average particle diameter of ceramic particles disposed inside the second conductive layer.

In the electrostatic chuck having the above-described configuration, the average particle diameter of the ceramic particles disposed inside the relatively thick first conductive layer is smaller than that in the related art, and falls within a size approximately equal to the average particle diameter of the ceramic particles disposed inside the relatively thin second conductive layer. With such a configuration, adhesion between the dielectric substrate and the first conductive layer can be sufficiently ensured.

According to the present invention, it is possible to provide an electrostatic chuck capable of ensuring adhesion between a dielectric substrate and a conductive layer.

### BRIEF DESCRIPTION OF THE DRAWINGS

FIG. 1 is a cross sectional view schematically illustrating a configuration of an electrostatic chuck according to a first embodiment;

FIGS. 2A and 2B are diagrams illustrating respective cross sections of an internal electrode and a heater;

FIGS. 3A and 3B are diagrams for explaining a method of manufacturing a dielectric substrate;

FIG. 4 is a cross sectional view schematically illustrating a configuration of an electrostatic chuck according to a second embodiment; and

FIG. 5 is a cross sectional view schematically illustrating a configuration of an electrostatic chuck according to a third embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W corresponds to an “a workpiece to be electrostatically attracted” , and is a silicon wafer, for example. The electrostatic chuck 10 may be used in an apparatus other than the semiconductor manufacturing apparatus.

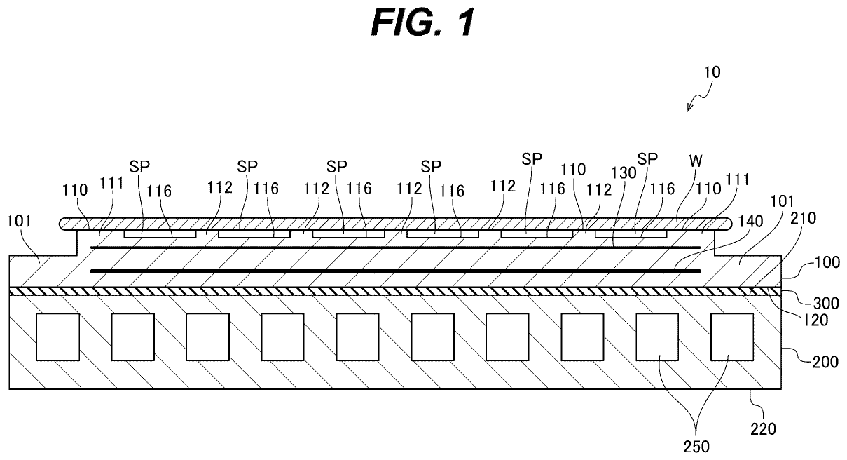

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

The dielectric substrate 100 of the present embodiment contains high-purity alumina having a purity of 99.5% or higher as a main component. The purity of the high-purity alumina contained as a main component in the dielectric substrate 100 is preferably 99.9% or higher, and is more preferably 99.99% or higher.

The “main component” means a compound contained in the largest amount in an object (herein, the dielectric substrate 100). Specifically, the “main component” means a compound that is confirmed, when quantitative analysis or semi-quantitative analysis is performed on the object using X-ray Diffraction (XRD), to be contained in the object in a relatively larger amount in terms of volume ratio or mass ratio than any other compound contained in the object.

A surface 110 on an upper side in FIG. 1 in the dielectric substrate 100 serves as a “mounting surface” on which the wafer W is mounted. A surface 120 on a lower side in FIG. 1 in the dielectric substrate 100 serves as a “surface to be joined” which is joined to the base plate 200 via a joining layer 300 which will be described later. A perspective in a case where the electrostatic chuck 10 is viewed from the surface 110 side along a direction perpendicular to the surface 110 will also be hereinafter expressed as “top view”.

The dielectric substrate 100 is provided with a rim portion 101. The rim portion 101 is a part protruding further toward an outer peripheral side relative to the surface 110 serving as the mounting surface. In top view, the rim portion 101 surrounds the entire surface 110 from an outer side. A surface on the wafer W side (surface on the upper side in FIG. 1) in the rim portion 101 is in a position on the base plate 200 side (lower side in FIG. 1) relative to the surface 110. When the wafer W is processed, an annular member referred to as a “focus ring” or the like which is not illustrated in the drawing is mounted on the rim portion 101.

A heater 140 is provided inside the dielectric substrate 100. The heater 140 is a conductor that is linearly routed, and generates heat by receiving power supplied from the outside to heat the dielectric substrate 100. The heater 140 is a thin planar layer made of a metallic material such as, for example, palladium, and is arranged so as to be parallel to the surface 110. As a material of the heater 140, molybdenum, platinum, tungsten, and the like may be used in addition to palladium. Power is supplied to the heater 140, for example, through a feed terminal which is not illustrated in the drawing and embedded on the surface 120 side of the dielectric substrate 100.

The heater 140 is routed along a path extending across substantially the entire dielectric substrate 100 in top view, but in FIG. 1, a cross section of the heater 140 is schematically illustrated as a single straight line. The dielectric substrate 100 may be divided into a plurality of regions in top view, and the heater 140 may be individually disposed for each of the respective regions. With such an aspect, a heating value of the heater 140 in each region can be individually adjusted. The heater 140 corresponds to a “first conductive layer” in the present embodiment.

At a height position on the surface 110 side relative to the heater 140 inside the dielectric substrate 100, an attraction electrode 130 is provided. The attraction electrode 130 is a thin planar layer made of a metallic material such as, for example, palladium, and is arranged so as to be parallel to the surface 110. As a material of the attraction electrode 130, molybdenum, platinum, tungsten, and the like may be used in addition to palladium. When a voltage is applied to the attraction electrode 130 from an outside via a feed line which is not illustrated in the drawing, an electrostatic force is generated between the surface 110 and the wafer W, and according to this, the wafer W is attracted and held. The single attraction electrode 130 may be provided as so-called a “monopolar” electrode as in the present embodiment, but may also include two attraction electrodes as so-called “bipolar” electrodes. Power is supplied to the attraction electrode 130, for example, through a feed terminal which is not illustrated in the drawing and embedded on the surface 120 side of the dielectric substrate 100. The attraction electrode 130 corresponds to a “second conductive layer” in the present embodiment.

As illustrated in FIG. 1, a space SP is formed between the dielectric substrate 100 and the wafer W. When a process such as etching is performed in the semiconductor manufacturing apparatus, an inert gas for temperature regulation is supplied to the space SP from the outside via a gas hole which is not illustrated in the drawing. When the inert gas is caused to be present between the dielectric substrate 100 and the wafer W, a thermal resistance between the dielectric substrate 100 and the wafer W is regulated, and according to this, a temperature of the wafer W is maintained at an appropriate temperature. As the inert gas for temperature regulation to be supplied to the space SP, a helium gas is used in the present embodiment, but the inert gas may be a gas of a type different from the helium gas.

A seal ring 111 and a dot 112 are provided on the surface 110 which serves as the mounting surface, and the space SP described above is formed around the seal ring 111 and the dot 112.

The seal ring 111 is an annular protrusion provided as a wall that defines the space SP at a position corresponding to an outermost circumference. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the mounting surface of the dielectric substrate 100. An upper end surface of each of the dots 112 becomes a part of the surface 110 and abuts against the wafer W. By providing the plurality of thus configured dots 112, warping of the wafer W is reduced.

The base plate 200 is a substantially disk-shaped member which supports the dielectric substrate 100. The base plate 200 is made of, for example, a metallic material such as aluminum. A surface 210 on the upper side in FIG. 1 in the base plate 200 serves as a “surface to be joined” which is joined to the dielectric substrate 100 via the joining layer 300.

The joining layer 300 is a layer provided between the dielectric substrate 100 and the base plate 200 to join those components. The joining layer 300 is obtained by causing an adhesive made of an insulating material to be cured. In the present embodiment, a silicone adhesive is used as the above-described adhesive. It is noted however that the joining layer 300 may be obtained by causing an adhesive of other types to be cured. In any case, in order that a thermal resistance between the dielectric substrate 100 and the base plate 200 is reduced, a material with a highest possible thermal conductivity is preferably used as the material of the joining layer 300.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

An insulating film may be formed on a surface of the base plate 200. The insulating film may be formed so as to cover only a part of the surface of the base plate 200, instead of the entire surface thereof. For example, the insulating film may be formed so as to cover only a side surface part excluding the surface 210 and the surface 220, that is, an exposed part exposed to plasma or the like inside the semiconductor manufacturing apparatus. Alternatively, the insulating film may be formed so as to cover a range including at least the entire surface 210. As the insulating film, for example, an alumina film formed by thermal spraying can be used. When the surface of the base plate 200 is covered by the insulating film, it is possible to increase dielectric withstand voltage of the base plate 200.

Specific configurations of the heater 140 (the first conductive layer) and the attraction electrode 130 (the second conductive layer) will be described. Both the heater 140 and the attraction electrode 130 are conductive layers provided inside the dielectric substrate 100, but they are not entirely formed of a conductor. The heater 140 and the attraction electrode 130 contain a plurality of ceramic particles CP inside, and are configured such that substantially the entire surroundings of the ceramic particles CP are filled with a conductor. That is, the plurality of ceramic particles CP are disposed inside the conductor. The ceramic particles CP refer to primary particles.

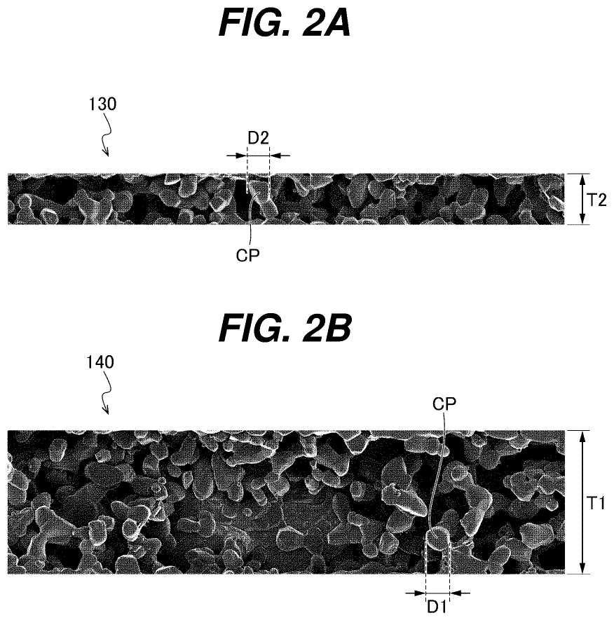

FIG. 2A illustrates an example of an image obtained by observing, with a scanning electron microscope, a portion of the attraction electrode 130 in a cross section which is obtained after a sample of the electrostatic chuck 10 is cut perpendicularly to the mounting surface. An upper end position of the image substantially matches an upper end position of the attraction electrode 130. A lower end position of the image substantially matches a lower end position of the attraction electrode 130. Before performing the observation with the scanning electron microscope, a portion of the conductor contained in the attraction electrode 130 in the vicinity of the above-described cross section has been removed in advance. Due to this, FIG. 2A illustrates a three-dimensional arrangement of the ceramic particles CP disposed inside the attraction electrode 130. That is, not only the ceramic particles CP located at the position of the cross section but also the ceramic particles CP located at a position on a back side relative to the cross section are illustrated.

FIG. 2B illustrates an example of an image obtained by observing, with a scanning electron microscope, a portion of the heater 140 in the above-described cross section. An upper end position of the image substantially matches an upper end position of the heater 140. A lower end position of the image substantially matches a lower end position of the heater 140. Before performing the observation with the scanning electron microscope, a portion of the conductor contained in the heater 140 in the vicinity of the above-described cross section has been removed in advance. Due to this, FIG. 2B illustrates a three-dimensional arrangement of the ceramic particles CP disposed inside the heater 140 similarly to FIG. 2A. A magnification of the image in FIG. 2B is the same as a magnification of the image in FIG. 2A.

As is clear from comparison of both images, a thickness T1 of the heater 140 is larger than a thickness T2 of the attraction electrode 130. Such a difference in thickness between the respective conductive layers is set in accordance with magnitude of a current flowing through each of the conductive layers. Almost no current flows through the attraction electrode 130 even when a high voltage is applied, so that the thickness T2 is set to be relatively small. Since the heater 140 is required to allow a large current to flow therethrough to generate Joule heat, the thickness T1 is set to be relatively large so that electrical resistance thereof becomes small. In the present embodiment, the thickness T2 of the attraction electrode 130 is about 4 μm, and the thickness T1 of the heater 140 is about 9 μm.

In FIG. 2B, a particle diameter of the ceramic particle CP disposed inside the heater 140 is shown as “D1”. In the following description, an average particle diameter of the plurality of ceramic particles CP disposed inside the heater 140 (the first conductive layer) will also be referred to as an “average particle diameter D1”.

In FIG. 2A, a particle diameter of the ceramic particle CP disposed inside the attraction electrode 130 is shown as “D2”. In the following description, an average particle diameter of the plurality of ceramic particles CP disposed inside the attraction electrode 130 (the second conductive layer) will also be referred to as an “average particle diameter D2”.

The “average particle diameter” means an average value of diameters of the respective ceramic particles CP disposed in the same conductive layer. The “diameter of the ceramic particle CP” means a diameter of a sphere when the ceramic particle CP is regarded as the sphere having the same volume as that of the ceramic particle CP.

In the electrostatic chuck 10 of the present embodiment, the average particle diameter D1 of the ceramic particles CP disposed inside the heater 140 is 50% or more and 150% or less of the average particle diameter D2 of the ceramic particles CP disposed inside the attraction electrode 130. That is, the heater 140 and the attraction electrode 130 are different from each other in their thicknesses, while the average particle diameters of the ceramic particles CP disposed inside them are substantially the same. In the present embodiment, the average particle diameters D1 and D2 are both about 1 μm.

To explain a reason why the average particle diameters D1 and D2 are set as described above, a manufacturing process of the dielectric substrate 100 will be briefly explained.

The dielectric substrate 100 of the present embodiment is manufactured by laminating a plurality of green sheets and firing a resulting laminate. The green sheet is formed by shaping a slurry containing ceramic raw material powder into a sheet.

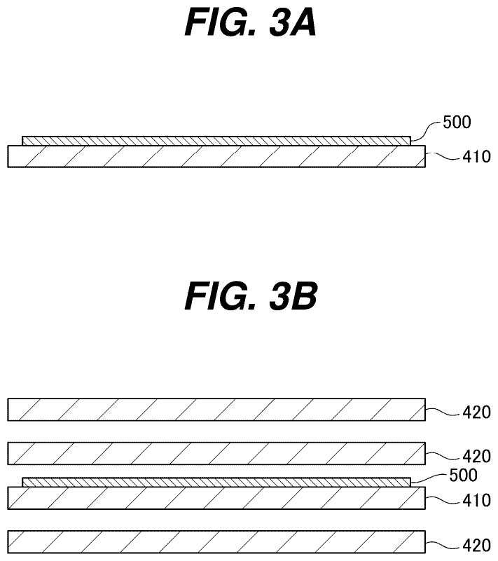

As illustrated in FIG. 3A, a conductive layer 500 made of a paste-like material is printed on a surface of some of green sheets 410. The conductive layer 500 is a portion that serves as the attraction electrode 130 or the heater 140 after firing. A material of the conductive layer 500 is, for example, a mixture in which powder of palladium and powder or the like containing the plurality of ceramic particles CP are mixed into a resin-based binder. By mixing the ceramic particles CP into the material of the conductive layer 500, it is possible to ensure adhesion between the ceramics constituting the dielectric substrate 100 and the heater 140 or the like located inside the dielectric substrate 100.

As illustrated in FIG. 3B, the green sheet 410 on which the conductive layer 500 is printed and a plurality of other green sheets 420 are laminated. In FIG. 3B, only one green sheet 410 on which the conductive layer 500 is printed is illustrated, but in the configuration of the present embodiment, two green sheets 410 on which the conductive layer 500 is printed are arranged. When the resulting laminate is fired, one conductive layer 500 becomes the attraction electrode 130, and the other conductive layer 500 becomes the heater 140. Thereafter, the dielectric substrate 100 according to the present embodiment is completed through processes such as polishing.

In screen printing, a thickness of the conductive layer 500 immediately after printing (that is, at the time of FIG. 3A) is appropriately adjusted so that the thickness corresponds to a thickness of the attraction electrode 130 after firing. Conventionally, the thickness of the conductive layer 500 is generally adjusted in accordance with particle diameters of the ceramic particles CP mixed into the material of the conductive layer 500. For example, in a case where the thickness T1 of the heater 140 is made larger than the thickness T2 of the attraction electrode 130 as in the present embodiment, particle diameters of the ceramic particles CP mixed into the conductive layer 500 that becomes the heater 140 may be made larger than particle diameters of the ceramic particles CP mixed into the conductive layer 500 that becomes the attraction electrode 130.

However, when the particle diameters of the ceramic particles CP contained in the heater 140 or the like are excessively large, adhesion between the ceramics constituting the dielectric substrate 100 and the heater 140 or the like is reduced. In addition, a problem may also occur in which an electrical resistance of the heater 140 or the like deviates from a design value since conductive paths in the heater 140 or the like become narrow. In contrast, if particle diameters of the ceramic particles CP contained in the heater 140 or the like become excessively small, adhesion of the heater 140 is reduced.

Thus, in the electrostatic chuck 10 according to the present embodiment, as described above, the ceramic particles CP disposed inside the heater 140 and the ceramic particles CP disposed inside the attraction electrode 130 are adjusted so that their average particle diameters become substantially the same as each other. While the thickness T1 of the heater 140 is made larger than the thickness T2 of the attraction electrode 130, by making the average particle diameter of the ceramic particles CP disposed inside the attraction electrode 130 smaller than that in the related art, adhesion of the heater 140 can be sufficiently ensured.

In the electrostatic chuck 10 of the present embodiment, the average particle diameter D1 of the ceramic particles CP disposed inside the heater 140 is 50% or more and 150% or less of the average particle diameter D2 of the ceramic particles CP disposed inside the attraction electrode 130. A range of the average particle diameter D1 may be confined within a narrower range centered on 100%. For example, by confining the average particle diameter D1 within a range of 90% or more and 110% or less of the average particle diameter D2, a further preferable effect can be obtained.

It is preferable that the average particle diameter D1 of the ceramic particles CP disposed inside the heater 140 be made smaller than 20% of the thickness T1 of the heater 140. By setting the average particle diameter D1 to such a size, adhesion of the heater 140 can be further enhanced.

To sufficiently ensure a thickness of the conductive layer 500 that becomes the heater 140 after printing as in FIG. 3A, for example, instead of increasing particle diameters of the ceramic particles CP mixed into the material of the conductive layer 500, particle diameters of palladium powder mixed into the same material may be made larger.

When an amount of impurities contained in the ceramics constituting the dielectric substrate 100 becomes small, adhesion between the ceramics and the heater 140 or the like tends to be reduced. Therefore, as in the present embodiment, in a case where the dielectric substrate 100 contains high-purity alumina as a main component, if particle diameters of the ceramic particles CP are increased as in the related art, adhesion of the heater 140 may be significantly reduced. Accordingly, in a case of using high-purity alumina as a material of the dielectric substrate 100, a necessity of adopting the configuration as in the present embodiment becomes particularly high.

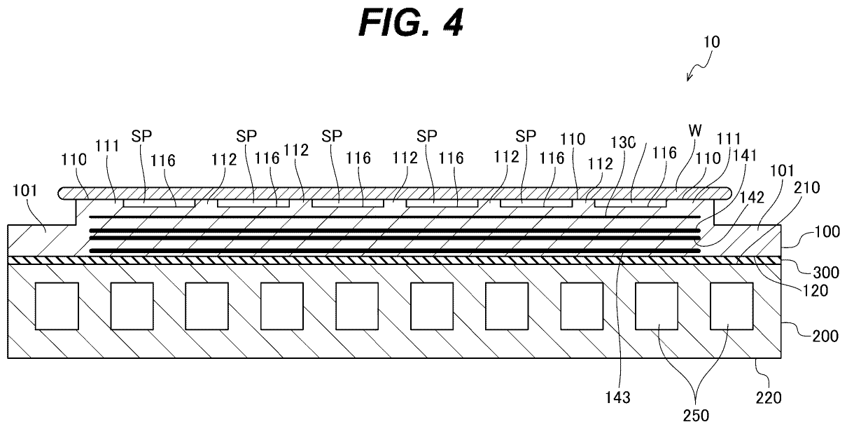

A second embodiment will be described with reference to FIG. 4. In the following, features different from those of the first embodiment will be mainly described, and description of features common to those of the first embodiment is omitted as appropriate. The present embodiment is different from the first embodiment in the configuration of the conductive layer disposed inside the dielectric substrate 100.

Inside the dielectric substrate 100 of the present embodiment, the attraction electrode 130, a heater 141, a heater 142, and a bypass 143 are provided in this order from the mounting surface side. A configuration of the attraction electrode 130 in the present embodiment is the same as the configuration of the attraction electrode 130 in the first embodiment.

Similarly to the heater 140 in the first embodiment, the heaters 141 and 142 generate heat by receiving power supplied from the outside to heat the dielectric substrate 100.

The heater 141 is routed individually in each of a plurality of divided regions in top view. Similarly, the heater 142 is also routed individually in each of a plurality of divided regions in top view. The regions for disposing the heater 141 are subdivided more finely than the regions for disposing the heater 142.

On the other hand, a heating value of the heater 141 per unit area is smaller than a heating value of the heater 142 per unit area. The heater 142 is used for raising the temperature of the entire wafer W or the like in a short time. The heater 141 is used for individually regulating a temperature of each part, and making an in-plane temperature distribution of the wafer W approximately uniform. Materials of the heaters 141 and 142 are the same as the material of the heater 140 in the first embodiment, but may be different materials in terms of electrical resistance or the like.

The bypass 143 is a conductive layer provided as an electric circuit for supplying power to each of the heaters 141 and 142 provided in plural. The bypass 143 is a thin planar layer formed of a metallic material, and is arranged so as to be parallel to the surface 110. A plurality of the bypasses 143 are provided corresponding to the number of the heaters 141 and 142. The bypass 143 electrically connects a feed terminal which is not illustrated in the drawing and embedded on the surface 120 side of the dielectric substrate 100, and the heater 141 or the like. By providing the bypass 143 as described above, it is possible to increase a degree of freedom in arranging the above-described feed terminal. A material of the bypass 143 is the same as the materials of the heaters 141 and 142, but may be a different material in terms of electrical resistance or the like.

In the present embodiment, thicknesses of the heaters 141 and 142 and the bypass 143 are substantially the same as the thickness T1 in the first embodiment, and are larger than the thickness T2 of the attraction electrode 130. The thicknesses of the heaters 141 and 142 and the bypass 143 may be different from each other within a range larger than the thickness T2 of the attraction electrode 130.

Similarly to the heater 140 in the first embodiment, the heaters 141 and 142 and the bypass 143 contain the plurality of ceramic particles CP inside. An average particle diameter of the ceramic particles CP disposed inside each of the heaters 141 and 142 and the bypass 143 is 50% or more and 150% or less of the average particle diameter of the ceramic particles CP disposed inside the attraction electrode 130.

That is, in the present embodiment, each of the heaters 141 and 142 and the bypass 143 corresponds to the “first conductive layer”, and the attraction electrode 130 corresponds to the “second conductive layer”. With such a configuration too, an effect similar to that described in the first embodiment can be attained.

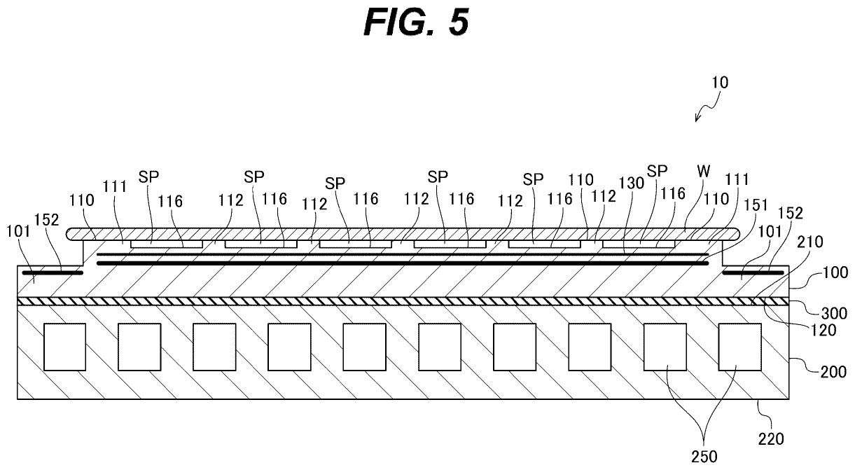

A third embodiment will be described with reference to FIG. 5. In the following, features different from those of the first embodiment will be mainly described, and description of features common to those of the first embodiment is omitted as appropriate. The present embodiment is also different from the first embodiment in the configuration of the conductive layer disposed inside the dielectric substrate 100.

The attraction electrode 130, an RF electrode 151, and an RF electrode 152 are provided inside the dielectric substrate 100 in the present embodiment. A configuration of the attraction electrode 130 in the present embodiment is the same as the configuration of the attraction electrode 130 in the first embodiment.

The RF electrodes 151 and 152 are provided as one of a pair of counter electrodes for generating plasma in the semiconductor manufacturing apparatus. The other of the counter electrodes is provided at a position on an upper side relative to the electrostatic chuck 10 in the semiconductor manufacturing apparatus. When high-frequency alternating-current voltage is applied between these counter electrodes, plasma is generated on the upper side of the wafer W and used for processing such as film deposition and etching on the wafer W.

The RF electrode 151 is disposed at a position inside the dielectric substrate 100 immediately below the mounting surface. A shape of the RF electrode 151 in top view is a substantially circular shape. The RF electrode 152 is disposed inside the rim portion 101 of the dielectric substrate 100. A shape of the RF electrode 152 in top view is a substantially annular shape. The RF electrodes 151 and 152 are both thin planar layers made of a metallic material such as, for example, palladium, and are arranged so as to be parallel to the surface 110.

The RF electrodes 151 and 152 are electrically connected to the base plate 200 via a member which is not illustrated in the drawing. Instead of such an aspect, it is possible to adopt an aspect such that the RF electrodes 151 and 152 are electrically connected to an external power source via a through hole which is not illustrated in the drawing and provided in the base plate 200.

In the present embodiment, thicknesses of the respective RF electrodes 151 and 152 are larger than the thickness T2 of the attraction electrode 130. The thicknesses of the RF electrodes 151 and 152 may be different from each other within a range larger than the thickness T2 of the attraction electrode 130.

Similarly to the heater 140 in the first embodiment, the RF electrodes 151 and 152 contain the plurality of ceramic particles CP inside. An average particle diameter of the ceramic particles CP disposed inside each of the RF electrodes 151 and 152 is 50% or more and 150% or less of the average particle diameter of the ceramic particles CP disposed inside the attraction electrode 130.

That is, in the present embodiment, each of the RF electrodes 151 and 152 corresponds to the “first conductive layer”, and the attraction electrode 130 corresponds to the “second conductive layer”. With such a configuration too, an effect similar to that described in the first embodiment can be attained.

Note that an aspect may be adopted in which only the attraction electrode 130 and the RF electrode 151 are disposed inside the dielectric substrate 100, and the RF electrode 152 is not disposed.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate having a mounting surface on which a workpiece to be electrostatically attracted is mounted;
a first conductive layer provided inside the dielectric substrate; and
a second conductive layer provided inside the dielectric substrate at a position closer to the mounting surface side than the first conductive layer, wherein
both the first conductive layer and the second conductive layer are configured such that a plurality of ceramic particles are disposed inside a conductor,
the first conductive layer is thicker than the second conductive layer, and
an average particle diameter of the ceramic particles disposed inside the first conductive layer is 50% or more and 150% or less of an average particle diameter of the ceramic particles disposed inside the second conductive layer.

2. The electrostatic chuck according to claim 1, wherein an average particle diameter of the ceramic particles disposed inside the first conductive layer is 90% or more and 110% or less of an average particle diameter of the ceramic particles disposed inside the second conductive layer.

3. The electrostatic chuck according to claim 1, wherein an average particle diameter of the ceramic particles disposed inside the first conductive layer is smaller than 20% of a thickness of the first conductive layer.

4. The electrostatic chuck according to claim 1, wherein the dielectric substrate contains high-purity alumina having a purity of 99.5% or higher as a main component.

5. The electrostatic chuck according to claim 1, wherein the second conductive layer is an attraction electrode.

6. The electrostatic chuck according to claim 1, wherein the first conductive layer is a heater.

7. The electrostatic chuck according to claim 1, wherein the first conductive layer is an RF electrode.
